(19) United States
(12) Patent Application Publication
(10) Pub. No.: US 2002/0097565 A1
(43) Pub. Date: Jul. 25, 2002

(54) Radio apparatus unit and radio apparatus housing

(76) Inventor: Arto Hietala, Oulu (FI)

Correspondence Address: PILLSBURY WINTHROP, LLP, P.O. BOX 10500, MCLEAN, VA, 22102, US

(21) Appl. No.: 10/021,552

(22) Filed: Dec. 19, 2001

Related U.S. Application Data
(63) Continuation of application No. PCT/FI00/00584, filed on Jun. 28, 2000.

(30) Foreign Application Priority Data
Jun. 29, 1999 (FI) 991481

(51) Int. Cl. H05K 7/14; H05K 5/00

(52) U.S. Cl. 361/756

(57) ABSTRACT

A connection between a printed circuit board of a radio apparatus unit and a printed circuit board of a radio apparatus housing, the connection being based on a guide member arranged on the radio apparatus unit's printed circuit board, the guide member being placed into a guide space on the radio apparatus housing to provide a good electrical coupling.

### FIELD OF THE INVENTION

The invention relates to a connection between a radio apparatus unit and a radio apparatus housing and to a method for arranging the radio apparatus unit into the radio apparatus housing. The invention also relates to a radio apparatus unit and a radio apparatus housing.

### BACKGROUND OF THE INVENTION

Radio apparatus units are usually arranged into radio apparatus housings having a separate shelf for each radio apparatus unit, the printed circuit board connectors in the radio apparatus units coinciding with the printed circuit board connectors in the radio apparatus housing. It is most important that the printed circuit board connectors are carefully aligned with each other to ensure a good electrical coupling and thereby the operation of the radio devices. Prior art teaches connector alignment solutions implemented without separate guide members, the connectors themselves acting as guide members when the radio apparatus unit is being installed in place. It is also known to use separate guide members, such as those described in U.S. Pat. No. 4,934,943. The solution disclosed in the publication is suitable particularly for vehicle radios where the radio device unit comprises moulded guide members on the sides of the device which set into groove-shaped guide elements on the radio device housing, thereby facilitating the interconnecting of the printed circuit board connectors.

The prior art solutions include several drawbacks. In solutions where separate guide members are not used, the positioning of the connectors is difficult, and the installation causes a significant strain on the connectors, possibly causing the connectors to bend or break if they are misaligned. Separate guide members placed for example into a radio apparatus unit comprising printed circuit boards also cause significant technical problems in the manufacture, because they increase the number of components to be tolerated, and therefore the tolerance chain becomes very long. The increase in the tolerance chain adds significantly to the costs of manufacture.

### BRIEF DESCRIPTION OF THE INVENTION

It is therefore an object of the invention to provide an improved method and an equipment implementing the method so as to allow a radio apparatus unit to be connected to a radio apparatus housing. This is achieved with the method described below, which is a method for arranging a radio apparatus unit into a radio apparatus housing. The method comprises the steps of arranging the radio apparatus unit into one or more support means in the radio apparatus housing; arranging one or more guide members on a printed circuit board of the radio apparatus unit into one or more guide spaces on a printed circuit board of the radio apparatus housing; fixing the radio apparatus unit in place into the radio apparatus housing using one or more fixing means.

The invention also relates to a printed circuit board of a radio apparatus unit. The printed circuit board is provided with one or more guide members for guiding the radio apparatus unit comprising the printed circuit board in place into the radio apparatus housing arranged for the radio apparatus unit.

The invention further relates to a printed circuit board of a radio apparatus housing. The printed circuit board comprises one or more guide spaces where one or more guide members of the radio apparatus unit's printed circuit board can be arranged.

The invention still further relates to a guide arrangement between a radio apparatus unit and a radio apparatus housing, the guide arrangement comprising a radio apparatus unit which comprises one or more printed circuit boards, which in turn comprise one or more connectors, the guide arrangement further comprising a radio apparatus housing for accommodating one or more radio apparatus units, the radio apparatus housing comprising one or more printed circuit boards, which comprise one or more connectors for arranging the one or more connectors of the radio apparatus unit's printed circuit board to the one or more connectors of the radio apparatus housing's printed circuit board. The one or more printed circuit boards of the radio apparatus unit are provided with one or more guide members, the one or more printed circuit boards of the radio apparatus housing being provided with one or more guide spaces where the guide members of the radio apparatus unit's printed circuit board can be placed when a connection is to be made.

The preferred embodiments of the invention are disclosed in the dependent claims.

The invention is based on the idea that the printed circuit board connectors of the radio apparatus unit are aligned with the printed circuit board connectors of the radio apparatus housing by using separate guide members arranged to the printed circuit boards, the guide members being placed to the guide spaces provided in the radio apparatus housing.

The method and equipment of the invention provide several advantages. Since the radio apparatus unit is arranged into the radio apparatus housing using separate guide members arranged to the radio apparatus unit's printed circuit board, the strain acting on the printed circuit board connectors at the installation of the printed circuit board is reduced because when the guide members are in place, the connectors are properly aligned. Moreover, the connectors on the printed circuit board are not easily damaged during the installation of the radio apparatus unit. The solution of the invention also provides significant advantages during use in that by supporting the printed circuit board, the guide members reduce the long-lasting strain acting on the connectors and possibly causing fatigue in the connector material and, in the long run, damage to the connectors. The solution of the invention also offers considerable advantages during the manufacture in that it reduces the tolerance chain, whereby it is sufficient that the tolerance for the location of the connectors in the radio apparatus unit's printed circuit board and the tolerance for the dimensions of the guide members are taken into account in the manufacture.

### BRIEF DESCRIPTION OF THE DRAWINGS

In the following the invention will be described in greater detail in connection with preferred embodiments and with reference to the accompanying drawings, in which

FIG. 1 shows a preferred embodiment of a radio apparatus housing according to the invention;

FIG. 2 is a front view of a preferred embodiment of the radio apparatus housing according to the invention with a radio apparatus unit according to a preferred embodiment of the invention installed in it;

FIG. 3 is a top view of a preferred embodiment of the radio apparatus housing according to the invention with a radio apparatus unit according to a preferred embodiment of the invention installed in it;

FIG. 4 is a side view of a preferred embodiment of the radio apparatus housing according to the invention with a radio apparatus unit according to a preferred embodiment of the invention installed in it;

FIG. 5 illustrates a preferred embodiment of a printed circuit board of a radio apparatus unit and a printed circuit board of a radio apparatus housing according to the invention;

FIG. 6 is a side view of the printed circuit boards of the radio apparatus unit and radio apparatus housing shown in FIG. 5.

### DETAILED DESCRIPTION OF THE INVENTION

In the following, the invention will be described with reference to base station cabinets used for example in mobile communications systems. Hereinafter the base station cabinets will be referred to as radio apparatus housings and units comprising radio equipment will be referred to as radio apparatus units. Although the invention will be described by means of preferred embodiments and with reference to radio apparatus units and radio apparatus housings, it is apparent that the invention is not restricted to these, but the solution of the invention for aligning printed circuit board connectors with the connectors of another printed circuit board can also be applied for example to microcomputers and similar devices where printed circuit boards comprising electronic components are used. The invention is particularly applicable to solutions where the printed circuit boards to be connected together are crosswise, i.e. they are substantially perpendicular to each other.

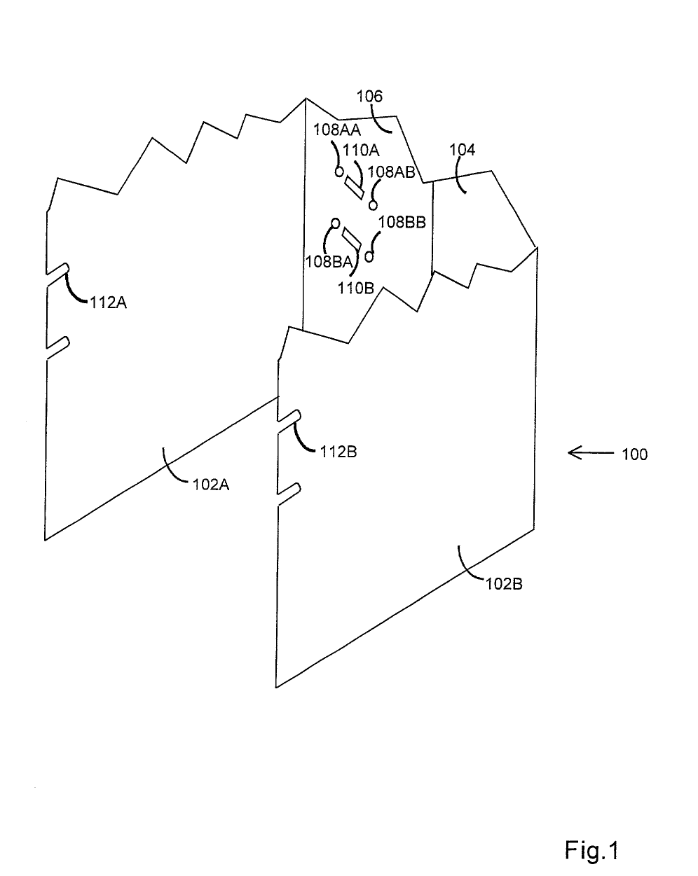

The radio apparatus unit and housing of the invention will be described below using a preferred embodiment and with reference to FIGS. 1 to 4. FIG. 1 shows a top right-hand view of a radio apparatus housing 100. The radio apparatus housing 100 comprises two side walls 102A-102B and a back wall 104. The back wall 104 is provided with two or more printed circuit boards 106 comprising connector units 110A-110B to be connected to the printed circuit board connectors of the radio apparatus unit. The printed circuit board can be attached to the radio apparatus housing 100 for example by means of screws, by soldering or using some other known method. In FIG. 1, the front wall of the radio apparatus housing 100 is open, thereby allowing the radio apparatus units to be placed into the radio apparatus housing 100 in such a way that the fixing means of the radio apparatus units are arranged into support means, such as fixing spaces 112A-112B of the radio apparatus housing 100, the fixing spaces being preferably groove-shaped openings. The grooves shown in FIG. 1 are relatively short. Grooves can, however, be made to extend for example halfway the side walls 102A-102B of the radio apparatus housing 100, which reduces the pressure acting on the connectors of the radio apparatus unit, because fixing means arranged halfway the side walls 102A-102B support the radio apparatus units better than fixing means arranged close to the open front side. The invention is not however, restricted to how the radio apparatus units are basically arranged into the radio apparatus housing 100. Instead of the described groove-shaped openings, it is also possible to apply a solution where each radio apparatus unit is arranged on a separate shelf in the radio apparatus housing. The inner side walls 102A-102B of the housing 100 can then both be provided with shelf-like protrusions arranged to support the radio apparatus units.

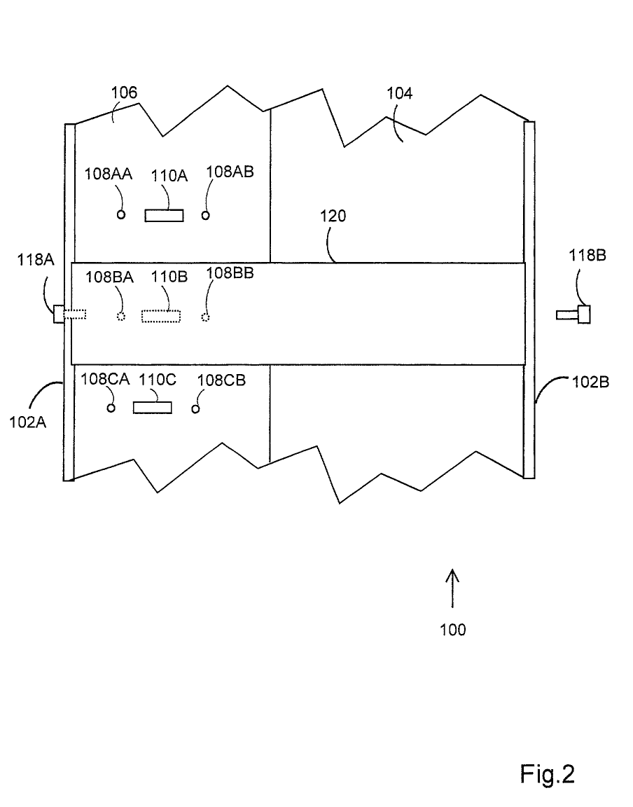

FIG. 2 shows the radio apparatus housing 100 of the invention seen from the direction of the open front wall, thereby making the inside of the rear wall 104 of the radio apparatus housing 100 visible. There is one radio apparatus unit 120 installed in the radio apparatus housing 100, the unit 120 in the Figure being attached at its left side by means of a fixing means 118A. The fixing means 118A-118B is preferably a screw which is attached through the fixing space of the radio apparatus housing 100 to the fixing space in the radio apparatus unit 120. The Figure shows that the back wall 104 of the radio apparatus housing 100 is provided with printed circuit boards 106 comprising preferably two guide spaces 108BA-108BB which are preferably annular holes into which the guide members of the radio apparatus unit 120 can be placed.

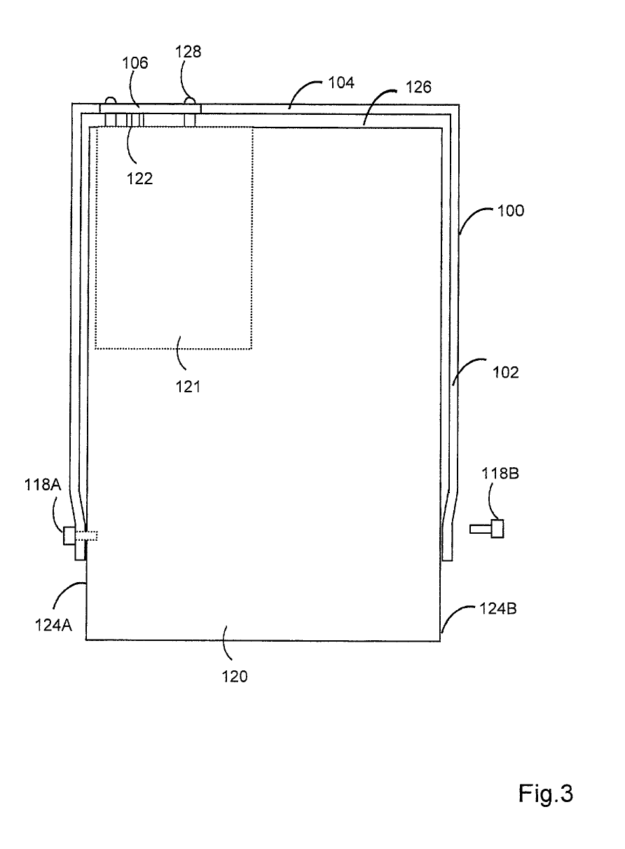

FIG. 3 shows a top view of the radio apparatus housing 100 a preferred embodiment of the invention. It is not essential to the invention whether the radio apparatus housing 100 comprises some kind of a cover solution, and therefore FIG. 3 illustrating the invention does not include one. The top view therefore shows the radio apparatus unit 120 installed into the radio apparatus housing 100, the unit 120 comprising a front panel, two side walls 124A-124B and a rear wall 126. The material of the radio apparatus unit 120 can be for example metal. Inside the radio apparatus unit 120 there is a printed circuit board 121 which may be attached to the radio apparatus unit 120 for example by means of screws, taps or some other known method. At the rear wall 126, which is to be installed against the back wall 104 of the radio apparatus housing 100, the radio apparatus unit's 120 printed circuit board 121 is provided with connectors 122 to be connected with the connectors on the radio apparatus housing's 100 printed circuit board 106 to provide an electric connection. The connectors on the printed circuit board 121 of the radio apparatus unit 120 are typically male plugs, whereas those in the radio apparatus housing 100 are female, socket-type connectors. The plug-type connectors can, however, be also arranged in the radio apparatus housing 100 and the socket-type connectors in the radio apparatus unit 120. FIG. 3 also shows a guide member 128 of the invention installed on the radio apparatus unit's 120 printed circuit board 121 for guiding the radio apparatus unit's 120 printed circuit board 121 to the appropriate place so that the contact between the radio apparatus unit 120 and the radio apparatus housing 100 is as good as possible. The guide members 128 are preferably slightly longer than the connectors 122 of the radio apparatus unit's 120 printed circuit board 121, which allows one or more guide members 128 to be first aligned to the guide spaces 108 in the radio apparatus housing 100 before the radio apparatus unit 120 is pushed into its final place.

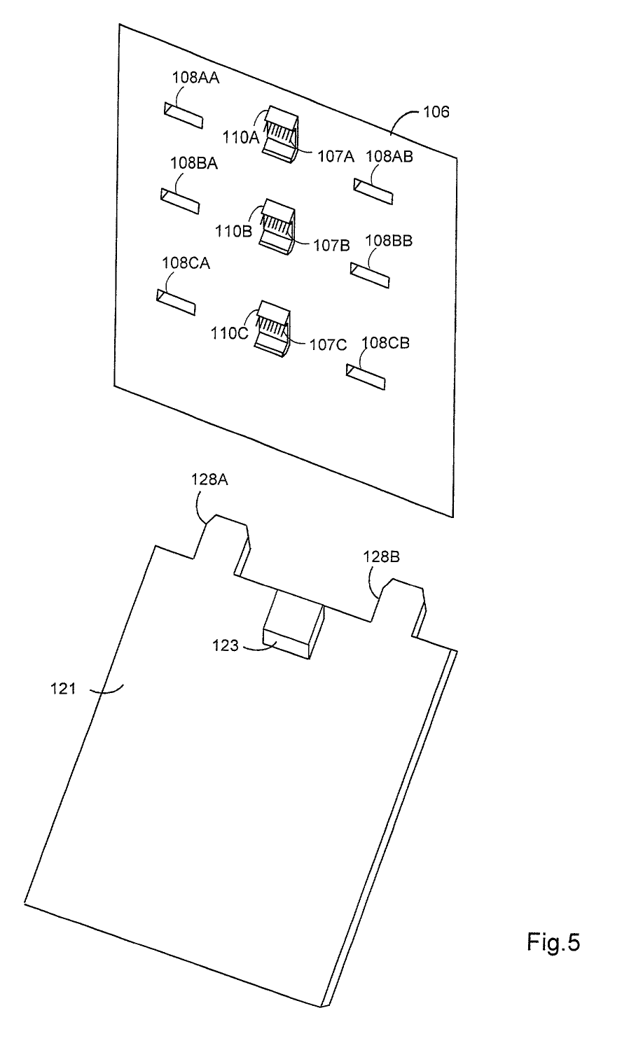

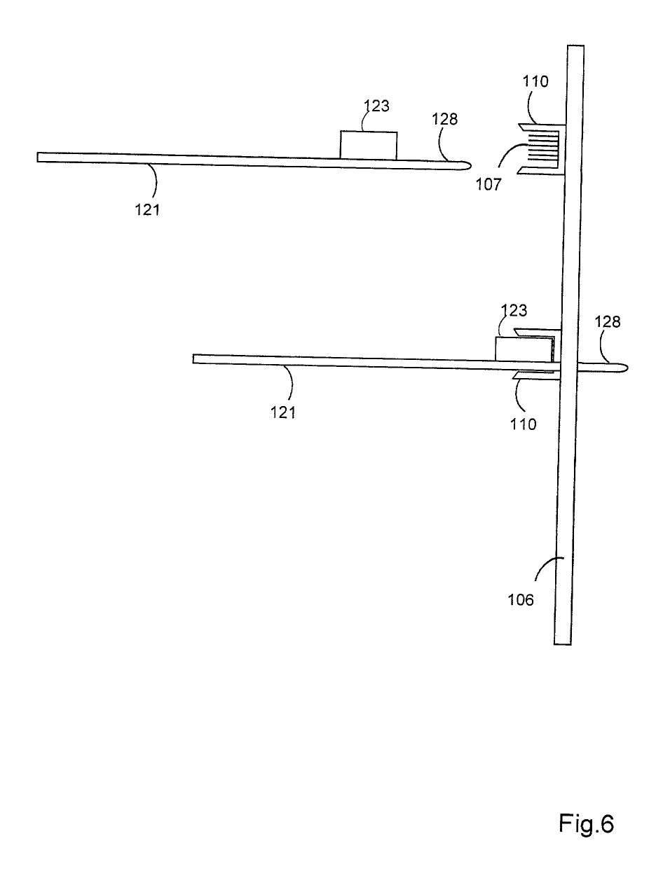

According to a preferred embodiment, the guide member 128 is a tap with an annular cross-section, the invention not being, however, limited to this. The form of the guide members 128 may equally well be quadratic, triangular, rectangular, a combination of these, or the like. There are preferably two guide members 128 on the radio apparatus unit's 120 printed circuit board 121 arranged so that one guide member 128 is substantially at both ends of the printed circuit board 121. The invention is not, however, restricted to two guide members 128, but there may be for example only one of them, installed in the middle of the printed circuit board 121, or, alternatively, there may be more than two guide members 128. The guide members 128 may be a part moulded to the printed circuit board 121 of the radio apparatus unit 120, or, alternatively, when the printed circuit board 121 is moulded, a thin spike is made on the board 121 where the guide member 128 can later be attached to as a separate part. As shown in FIGS. 5 and 6, according to a preferred embodiment, the guide member 128 can also be an integral part of the printed circuit board 121, in which case the printed circuit board 121 is formed such that it has one or more guide members 128 at one end. It is apparent to a person skilled in the art that the invention is not restricted to the method of arranging the guide members 128 to the printed circuit board 121. The guide members 128 can be made of metal, plastic, or the like, but their material is not essential to the invention.

FIG. 3 further shows that when the radio apparatus unit 120 is installed in its place, the guide members 128 of the printed circuit board 121 preferably penetrate the guide spaces arranged on the printed circuit board 106 of the radio apparatus housing 100. Although the guide spaces 108 of the radio apparatus housing 100 are described substantially annular in FIG. 2, the invention is not restricted to this solution, but the guide spaces follow the forms of the guide members 128 of the radio apparatus unit 120, so their form may be quadratic, triangular, rectangular, a combination of these, or the like. It is also possible that the back wall 104 of the radio apparatus housing 100 is provided with socket-type protrusions into which the guide members 128 of the printed circuit board 121 of the radio apparatus units 120 set, without penetrating the back wall 104 of the radio apparatus housing 100.

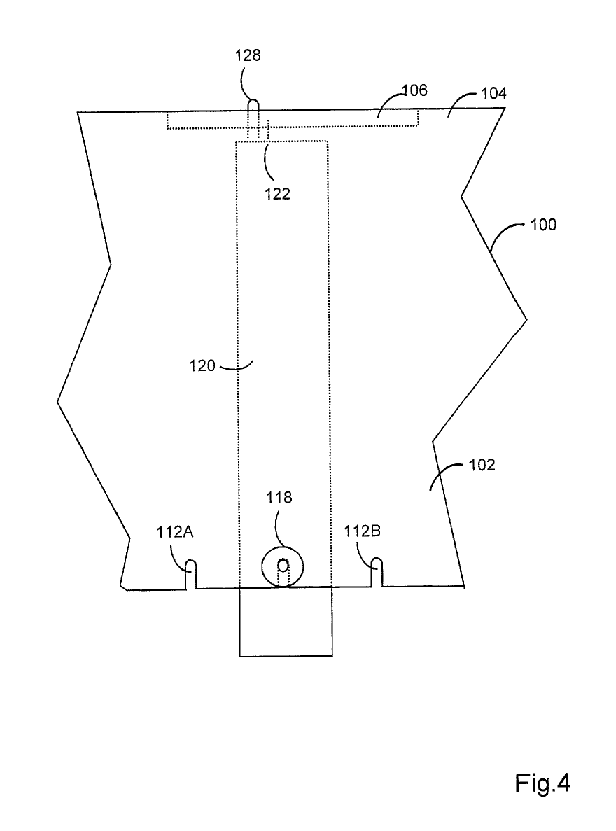

FIG. 4 shows the radio apparatus housing 100 of the invention and a side view of the radio apparatus unit 120 of the invention installed in the radio apparatus housing 100. Although the radio apparatus unit 120 shown in the Figure is attached at its sides, side attaching is not essential to the invention, but the radio apparatus units 120 can also be attached to the housing using rails or shelves. Also in solutions where shelves are used to install the radio apparatus unit 120 in the housing 100 using, the actual aligning of the radio apparatus unit's 120 printed circuit board 121 connectors 122 with the connectors of the radio apparatus housing 100 is carried out using the guide members 128 and the guide spaces 106 of the radio apparatus housing 100.

FIG. 5 shows the essential parts of a structure of the radio apparatus unit's 120 printed circuit board 121 and radio apparatus housing's 100 printed circuit board 106 of the invention according to a preferred embodiment. The printed circuit board 106 of the radio apparatus housing 100 shown in the Figure comprises one or more connecting units 110A-110C, provided with connector sets 107A-107C, respectively. For the sake of clarity, the connecting units 110A-110C shown in the Figure comprise only a few connectors, but in practice the connecting units 110A-110C. can naturally have more connectors 107A-107C. The printed circuit board 106 of the radio apparatus housing 100 also comprises guide spaces 108AA-108CB which are shown in FIG. 5 as rectangular openings through which the guide members 128A-128B of the radio apparatus unit's 120 printed circuit board 121 can be installed. The radio apparatus unit's 120 printed circuit board 121 in turn comprises connectors, to be connected to the corresponding printed circuit board 106 of the radio apparatus housing 100, which is arranged into a separate connecting unit 123, which according to a preferred embodiment is a case arranged on top of the surface plane of the printed circuit board 121. FIG. 5 illustrates a preferred embodiment according to which the guide members 128A-128B of the radio apparatus unit's 120 printed circuit board 121 are substantially rectangular protrusions arranged to the printed circuit board 121, the printed circuit board 121 being formed such that on the printed circuit board 121 side resting against the radio apparatus housing 100, the printed circuit board 121 has two portions that are arranged into the guide spaces 108A-108B of the radio apparatus housing 100. The ends of the guide members 128A-128B are preferably slightly beveled to facilitate their arrangement into the guide spaces, e.g. 108A-108B.

FIG. 6 illustrates a side view of the radio apparatus housing's 100 printed circuit board 106 shown in FIG. 5 and the radio apparatus unit's 120 printed circuit board 121 to be installed in the housing 100. The upper printed circuit board 121 shows the unit prior to its installation and the lower one after the installation. The lower printed circuit board 121 shows that the guide members 128 of the printed circuit board 121 preferably penetrate the printed circuit board 106 of the radio apparatus housing 100 to some extent, thereby ensuring the best possible support to hold the printed circuit board 121 in place.

The tolerance chain of the radio apparatus unit of the invention shown in FIGS. 5 and 6 is shorter than in the conventional solution where the printed circuit board is attached to the radio apparatus unit by means of a positioning pin, the radio apparatus unit comprising a guide pin to be arranged into a guide hole on the radio apparatus housing. Table 1 compares the number of components to be tolerated in the solution of the invention with those in prior art solutions.

TABLE 1
Comparison of the tolerance chain in a prior art
solution with the solution of the invention

| Component to be tolerated | Invention | Prior art |
|---|---|---|
| Size of the unit's guide pin | X | X |
| Positioning of the unit's guide pin | | X |
| Positioning hole on the unit's printed circuit board | | X |
| Positioning pin on the unit's printed circuit board | | X |
| Positioning of the unit's printed circuit board | X | X |
| connector | | |
| Guide pin hole on the housing's printed circuit | X | X |
| board | | |
| Positioning of the guide pin hole on the housing's | X | X |
| printed circuit board | | |
| Positioning of the connector on the housing's | X | X |
| printed circuit board | | |

Table 1 shows that as regards the radio apparatus unit, it suffices in the solution of the invention to ensure that the size of the guide pins in the radio apparatus unit is within the tolerance limits, and that the printed circuit board connectors of the radio apparatus unit are in place. As regards the radio apparatus housing, tolerance is required for the size of the printed circuit board's guide pin hole, which is to receive the unit's printed circuit board pin. Tolerance is further required for the location of the hole, and to the positioning of the radio apparatus unit's printed circuit board connectors with respect to the hole arranged for the housing's guide pin. With regard to the radio apparatus housing, the above described tolerance chain of the invention does not differ from the prior art solution. However, with regard to the prior art radio apparatus unit, where the guide pin is located in the radio apparatus unit, the tolerance chain comprises more components than the solution of the invention, i.e. the tolerance for the positioning of the unit's guide pin, and tolerances for the positioning hole and positioning pin in the unit. Table 1 thus shows that due to the shortening of the tolerance chain, the solution of the invention provides clear manufacturing and economic advantages compared with the prior art.

Although the invention is described above with reference to an example shown in the attached drawings, it is apparent that the invention is not restricted to it, but may vary in many ways within the inventive idea disclosed in the attached claims.

1. A printed circuit board of a radio apparatus unit, characterized in that the printed circuit board is provided with one or more guide members for guiding the radio apparatus unit comprising the printed circuit board in place into a radio apparatus housing where one or more radio apparatus units can be placed, which one or more guide members at the radio apparatus unit's printed circuit board are meant to be guided into one or more guide spaces on the printed circuit board of the radio apparatus housing.

2. A printed circuit board according to claim 1, characterized in that the one or more guide members are substantially rectangular.

3. A printed circuit board according to claim 1, characterized in that the one or more guide members are protruding parts made of the printed circuit board material and located on the printed circuit board.

4. A printed circuit board according to claim 1, characterized in that the upper and lower surfaces of the one or more guide members are substantially level with the printed circuit board.

5. A printed circuit board according to claim 1, characterized in that the radio apparatus unit's printed circuit board comprises one or more connectors to be connected to the connectors of the radio apparatus housing's printed circuit board and that the one or more guide members of the radio apparatus unit's printed circuit board are located at the same side of the radio apparatus unit's printed circuit board as the one or more connectors of the radio apparatus unit's printed circuit board.

6. A printed circuit board of a radio apparatus housing, characterized in that the printed circuit board comprises one or more guide spaces where one or more guide members of the radio apparatus unit's printed circuit board can be arranged.

7. A printed circuit board according to claim 6, characterized in that the one or more guide spaces are substantially rectangular.

8. A method for arranging a radio apparatus unit into a radio apparatus housing, characterized by comprising the steps of
arranging the radio apparatus unit into one or more support means in the radio apparatus housing;
arranging one or more guide members on a printed circuit board of the radio apparatus unit into one or more guide spaces on a printed circuit board of the radio apparatus housing;
fixing the radio apparatus unit in place into the radio apparatus housing using one or more fixing means.

9. A method according to claim 8, characterized in that the one or more guide members of the radio apparatus unit's printed circuit board are on the same side of the radio apparatus unit's printed circuit board as the one or more connectors of the radio apparatus unit's printed circuit board.

10. A method according to claim 8, characterized in that the guide members of the radio apparatus unit's printed circuit board are substantially rectangular protrusions arranged to be substantially level with the printed circuit board, and that the guide space of the radio apparatus unit's printed circuit board is a substantially rectangular opening.

11. A method according to claim 8, characterized in that the one or more support means of the radio apparatus housing are shelf-like protrusions on the side wall of the radio apparatus housing which are arranged to hold the radio apparatus unit.

12. A method according to claim 8, characterized in that the one or more attaching means is a screw, or the like, with which the radio apparatus unit can be attached to the radio apparatus housing.

13. A guide arrangement between a radio apparatus unit and a radio apparatus housing, the guide arrangement comprising a radio apparatus unit which comprises one or more printed circuit boards, which in turn comprise one or more connectors, the guide arrangement further comprising a radio apparatus housing for holding one or more radio apparatus units, the radio apparatus housing comprising one or more printed circuit boards, which comprise one or more connectors for arranging one or more connectors of the radio apparatus unit's printed circuit board to one or more connectors of the radio apparatus housing's printed circuit board, characterized in that the one or more printed circuit boards of the radio apparatus unit are provided with one or more guide members, and that the one or more printed circuit boards of the radio apparatus housing are provided with one or more guide spaces where the guide members of the radio apparatus unit's printed circuit board can be placed when a connection is to be made.

14. A guide arrangement according to claim 13, characterized in that the one or more guide members of the radio apparatus unit's printed circuit board are on the same side of the radio apparatus unit's printed circuit board as the one or more connectors.

15. A guide arrangement according to claim 13, characterized in that the one or more guide members of the radio apparatus unit's printed circuit board are substantially rectangular.

16. A guide arrangement according to claim 13, characterized in that the one or more guide members of the radio apparatus unit are protruding parts formed of the printed circuit board material onto the printed circuit board.

17. A guide arrangement according to claim 13, characterized in that the upper and lower surfaces of the one or more guide members of the radio apparatus unit are substantially level with the radio apparatus unit's printed circuit board.

18. A guide arrangement according to claim 13, characterized in that the one or more guide spaces at the radio apparatus unit's printed circuit board are substantially rectangular openings.

19. A guide arrangement according to claim 13 characterized in that the one or more guide spaces are on the radio apparatus housing's printed circuit board.
